(19) United States
(12) Patent Application Publication
(10) Pub. No.: US 2014/0376195 A1
(43) Pub. Date: Dec. 25, 2014

(54) Methods of forming dual sided coreless package structures with land side capacitor

(71) Applicants: Qinglei Zhang, Chandler, AZ (US); Amruthavalli P. Alur, Tempe, AZ (US)

(72) Inventors: Qinglei Zhang, Chandler, AZ (US); Amruthavalli P. Alur, Tempe, AZ (US)

(21) Appl. No.: 13/926,135

(22) Filed: Jun. 25, 2013

(51) Int. Cl. H05K 3/46; H05K 1/18; H05K 1/03; H05K 3/34

(52) U.S. Cl. CPC H05K 3/4682; H05K 3/3431; H05K 1/181; H05K 1/03; H05K 2203/04; H05K 2203/072; H05K 2203/0723
USPC 361/748; 228/165; 228/176; 174/260

(57) ABSTRACT

Methods of forming coreless package structures comprising backside land side capacitors (LSC) and dual sided solder resist are described. Those methods and structures may include forming a nickel coating on a first and second side of a core, forming a conductive plating on the nickel coating, forming building up layers on the conductive plating to form two panels on the core, de-paneling the panels from the core to form two coreless substrates, forming a laminate on the first and second sides of the coreless substrates, and forming an LSC on a backside of the coreless substrates.

### BACKGROUND OF THE INVENTION

As semiconductor technology advances for higher processor performance, advances in packaging architectures may include coreless package structures, such as bumpless build-up Layer (BBUL-C) package architectures and other such assemblies. Current process flows for coreless packages involve building the substrate up on a temporary core/carrier capped with copper foil, which is then etched off after the package is separated from the core.

### BRIEF DESCRIPTION OF THE DRAWINGS

While the specification concludes with claims particularly pointing out and distinctly claiming certain embodiments, the advantages of these embodiments can be more readily ascertained from the following description of the invention when read in conjunction with the accompanying drawings in which:

FIGS. 1a-1r represent cross-sectional views of structures accord to embodiments.

FIG. 2 represents a flow chart according to embodiments.

FIG. 3 represents cross-sectional views of a system according to embodiments.

FIG. 4 represents a schematic of a system according to embodiments.

### DETAILED DESCRIPTION OF THE P RESENT INVENTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments. The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views.

Methods and associated structures of forming and utilizing microelectronic structures, such as package structures/substrates comprising dual sided solder resist with back side land side capacitors, are described. Those methods/structures may include forming a nickel coating on a first and second side of a core, forming a conductive plating on the nickel coating, forming building up layers on the conductive plating to form a first and second panel disposed on the first and second sides of the core, de-paneling the panels from the core, forming a laminate on the first and second sides of the panels, and forming a land side capacitor (LSC) on a backside of the panels. The coreless package structures of he embodiments herein enable dual sided processing of coreless architectures, wherein the coreless substrates comprise dual sided solder resist on the outer surface with backside LSC capability.

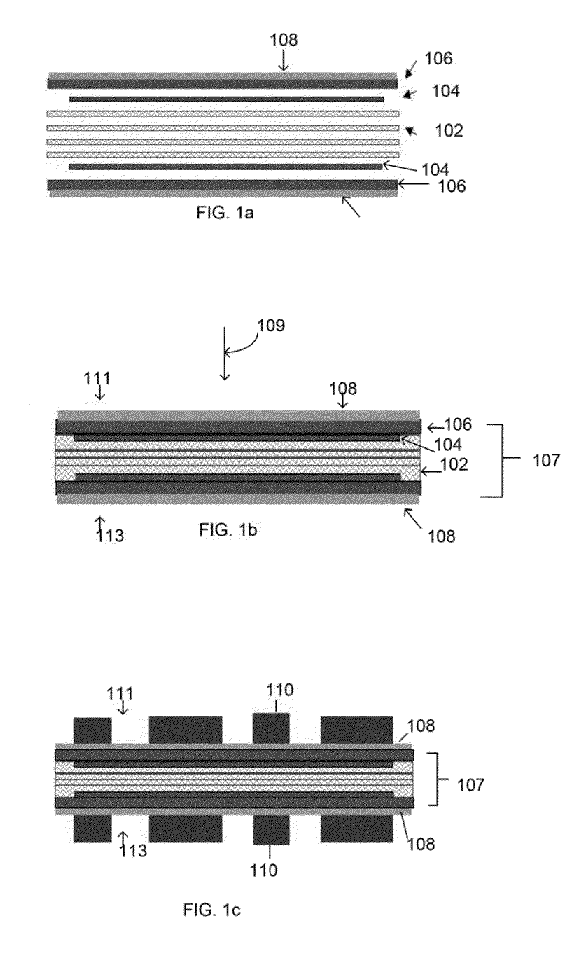

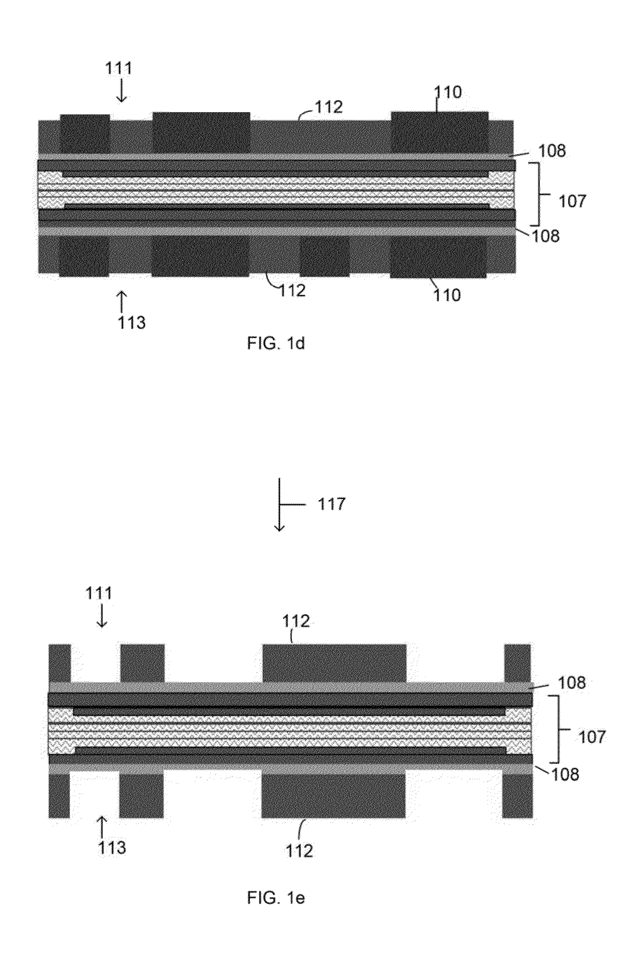

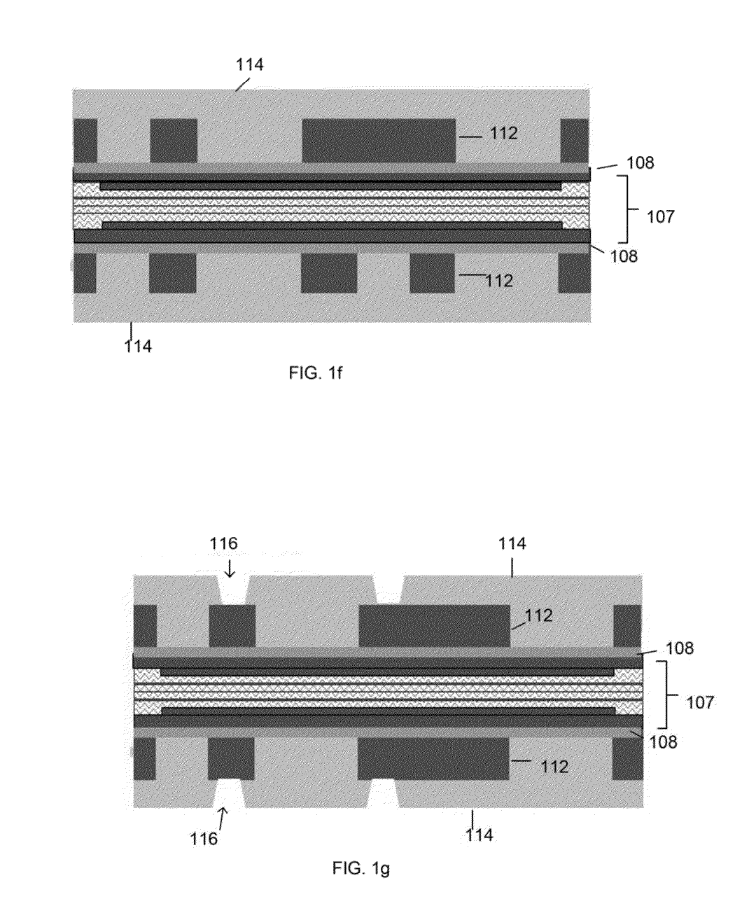

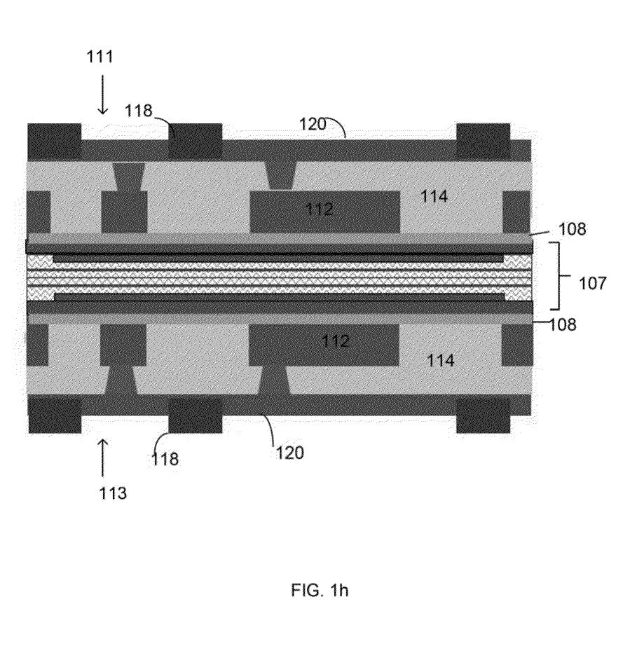

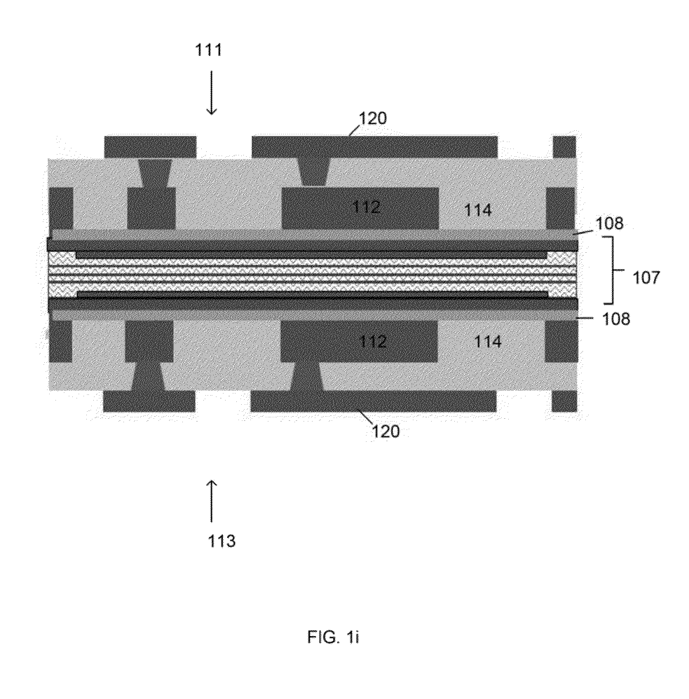

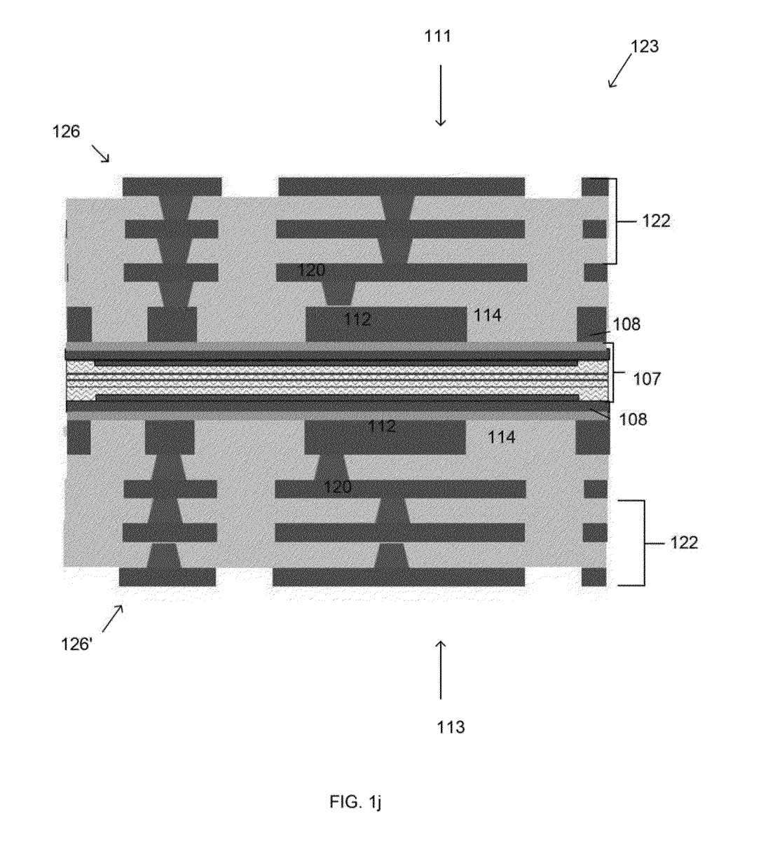

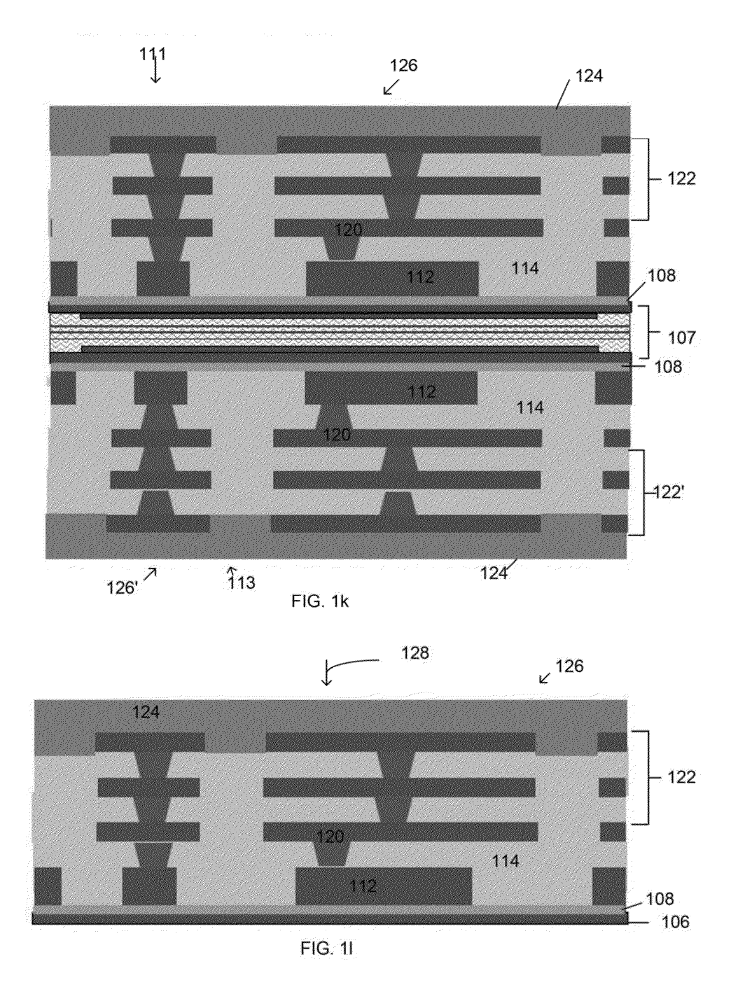

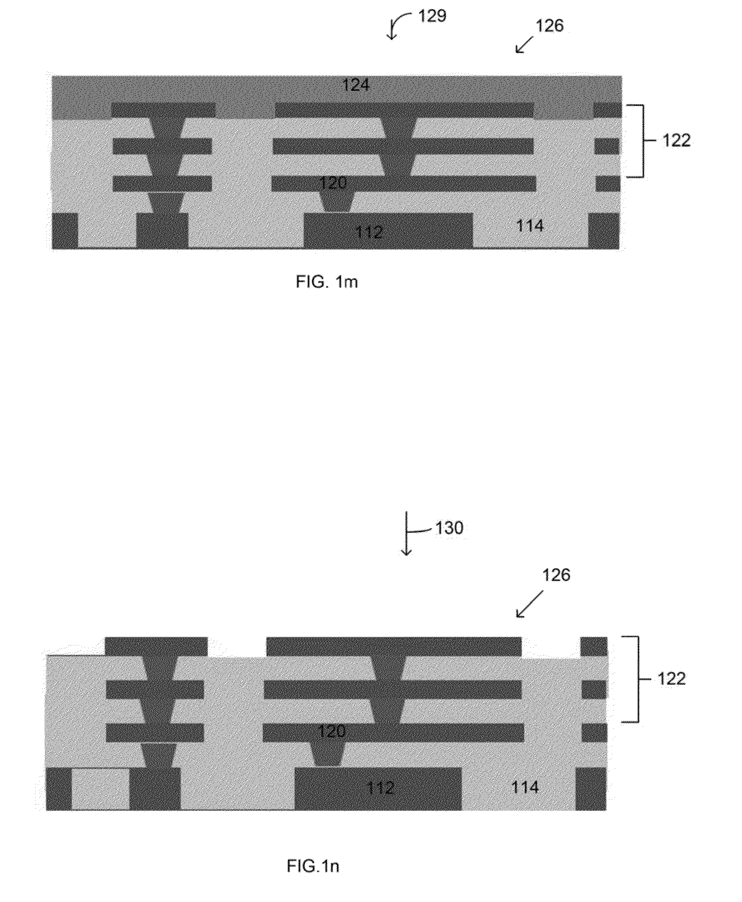

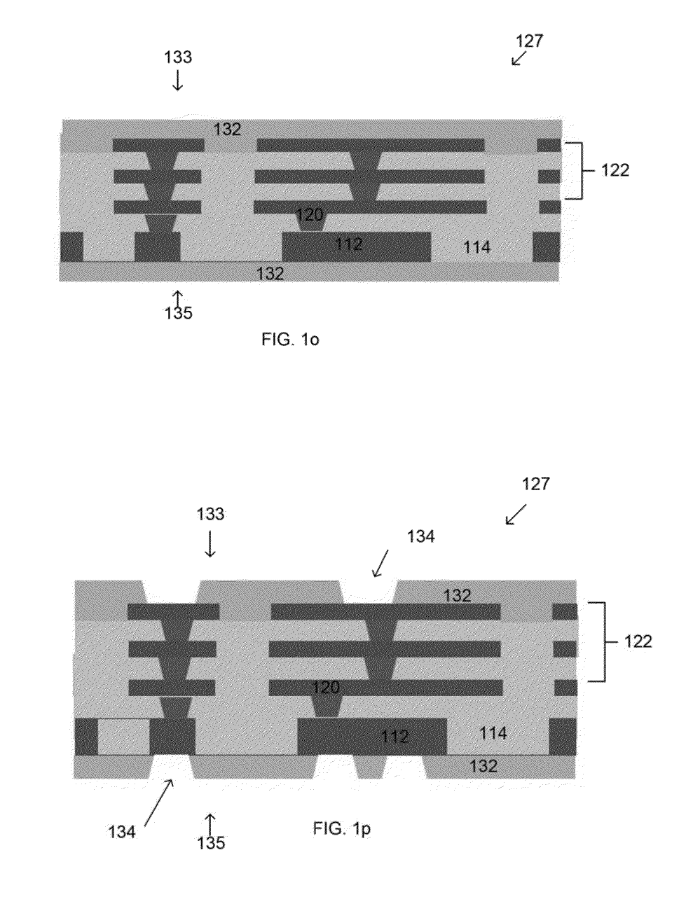

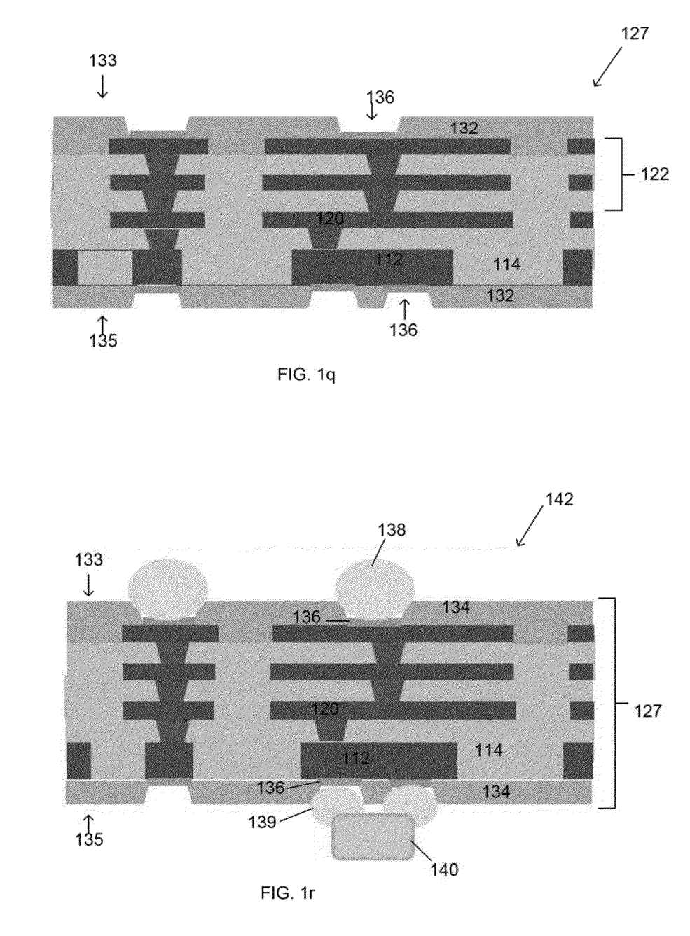

FIGS. 1a-1r depict cross-sectional views of embodiments of forming coreless panel substrate structures. In FIG. 1a, a plurality of prepreg materials 102 may comprise a dielectric material, and may comprise a portion of a prepreg core. A thin foil 104 may be stacked upon both sides of the prepreg material 102, and a thick foil 106 may be stacked on the thin foil 104. In an embodiment, the thin and thick foil 104, 106 may comprise a copper material, and their respective thicknesses may be optimized depending upon the requirements of a particular application. A conductive coating 108, which may comprise a nickel coating in an embodiment, may be formed on the thick foil 106 on both sides of the prepreg material 102. In an embodiment, the conductive coating 108 may further comprise at least one of gold and palladium.

The prepreg material 102, the thin and thick foils 102, 104 (which may comprise copper foils in an embodiment), and the conductive coating 108, may be pressed together utilizing a suitable pressing techniques 109 with which to form a prepreg core 107 comprising the conductive coating 108 on (FIG. 1b). The prepreg core 107 may comprise a first side 111 and a second side 113. In an embodiment, a mask resist 110 may be formed on the conductive coating 108 on the first side 111 and the second side 113 of the prepreg core 107 (FIG. 1c).

In an embodiment, a conductive plating 112 may be formed on the conductive coating 108 disposed on the first side 111 and the second side 113 of the prepreg core 107 (FIG. 1d). In an embodiment, the conductive plating 112 may be formed by an electroplating process, wherein a conductive material, such as copper, may be electroplated on the first and second sides 111, 113 of the prepreg core 107. In an embodiment, a seed layer may be formed (not shown) prior to electroplating the conductive plating 112. In an embodiment, the conductive plating 112 may be patterned by the mask resist 110, which may comprise a dry film resist material in an embodiment. In an embodiment, the conductive plating 112 may comprise side at least one of a ball grid array (BGA) pad and a land side capacitor (LSC) pad.

In an embodiment, the mask resist 110 may be removed using a suitable removal process 117 (FIG. 1e). In the case where a seed layer is formed prior to conductive plating 112 formation the seed layer may be removed as well. In an embodiment, a dielectric material 114 may be formed/laminated on the conductive plating 112 disposed on both sides 111, 113 of the core 107 (FIG. 1f). In an embodiment, the dielectric material 114 may comprise an Ajinomoto® Build up Film (ABF) material.

Openings 116 may be formed in the dielectric material 14 (FIG. 1g), which may comprise vias 116 in an embodiment. The openings 116 may be formed using laser processing methods in an embodiment. A resist material 118 may be formed on the dielectric material 116 (FIG. 1h). Electroless and electrolytic processing may be utilized to form a conductive layer 120 on the dielectric material 114 on both sides 111, 113 of the core 107. The conductive layer 120 may be physically and electrically coupled with the conductive plating 112. The resist material 118 may be removed (FIG. 1i). Further layers of dielectric material separated by conductive layers may be formed utilizing a semi-additive processing technique to form a plurality of buildup layers 122 on the conductive layer 120 disposed on the first and second sides 111, 113 of the core 107 (FIG. 1j) to form a first panel 126 and a second panel 126′ disposed on the first and second sides 111, 113 of the core 107. In an embodiment, a multi layer dual sided coreless panel 123 may be formed.

A dry film resist 124 may be laminated on the first and second panels 126, 126′ (FIG. 1k). The first and second panels 126, 126′ may be de-paneled from the core 107 (FIG. 1l). The dry film resist 124 provides support for the panels 126, 126′ during the de-paneling process 128. In an embodiment, the thick foil 106 and the conductive coating 108 may be removed using any suitable removal/etching process 109 (FIG. 1m, depicting the first panel 126 only. Additionally, the first panel only is depicted for convenience subsequently herein).

The dry film resist 124 provides protection for the top conductive layers of the build up layers 122. The dry film resist 124 may be removed 130 from both the panels 126, 126′ (FIG. 1n) after de-paneling. A laminate 132 may be formed on a first side 133 and a second side 135 of both panels 126, 126′, wherein coreless substrates 127, 127′ comprising dual sided laminate 132 are formed (FIG. 1o (depicting only coreless substrate 127 for convenience subsequently herein). In an embodiment, the laminate 132 may comprise a thickness of about 10 to about 30 microns, but may vary according to the particular application. In an embodiment, the laminate 132 may comprise a solder resist 132. Openings 134 may be formed in the laminate 132 that is disposed on both the first and second sides 133, 135 of both the coreless substrates 127, 127′ (FIG. 1p).

A surface finish may be performed, wherein pads 136 may be formed in the openings 134 in the laminate 134 that is disposed on both sides 133, 135 of the coreless substrates 127, 127′ (FIG. 1q). In an embodiment, the pads 136 may comprise solder pads 136. In an embodiment, connective bumps 138, which may comprise solder interconnect bumps, may be attached to the pads 136 disposed on the first side 133 of the coreless substrates 127, 127′. Land side capacitor bumps 139, which may comprise solder interconnect bumps, may be attached to the pads 136 disposed on the second side 135 of the panels 126, 126′.

A land side capacitor 140 may be attached to the land side capacitor conductive bumps 139 disposed on the second side 135 of the coreless substrates 127, 127′ (FIG. 1r). In an embodiment, the coreless substrates 127, 127′ may comprise a portion of a coreless package structure 142 that may comprise back side landside capacitor 140 with dual sided solder resist 132 disposed on outer surfaces of the coreless substrate 127, 127′. In an embodiment, the land side capacitor 140 is directly disposed on two adjacent land side capacitor bumps 139. The exact number of bumps attached to the land side capacitor 140 may depend upon the particular application, in some cases. In an embodiment, each of the adjacent land side capacitor bumps 139 that may be directly coupled to the land side capacitor 140 may be disposed, at least partially, within the openings 134 in the laminate 132, and may be both coupled with the conductive layer 112 disposed within the coreless substrate 127. In an embodiment, the conductive layer 112 may comprise a land side capacitor pad 112 that may be coupled with the adjacent land side capacitor bumps 139, wherein the land side capacitor bumps 139 are coupled with the land side capacitor pad 112 to the conductive plating 12 in the same plane of metallization.

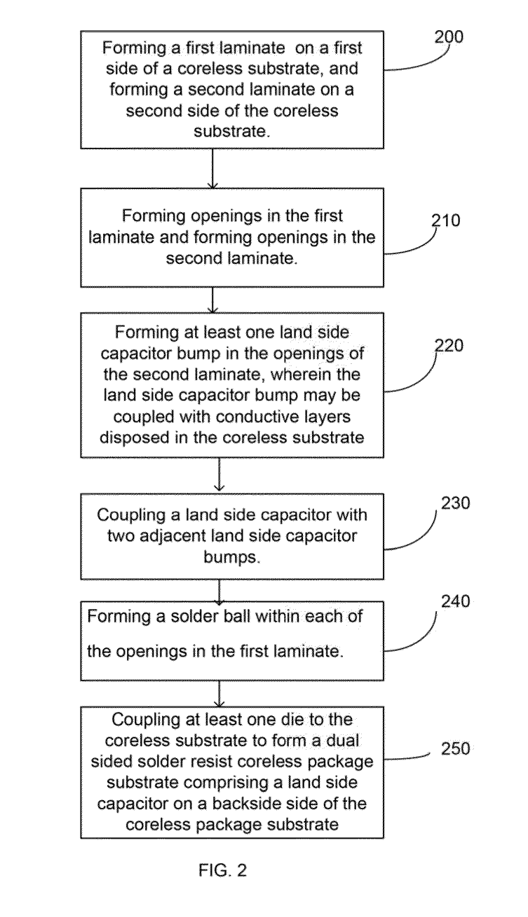

FIG. 2 depicts a flow chart of a method according to another embodiment. At step 200, a first laminate may be formed on a first side of a coreless substrate, and a second laminate may be formed on a second side of the coreless substrate. At step 210, openings may be formed in the first laminate and in the second laminate. At step 220, at least one land side capacitor pad may be formed in the openings of the second laminate, wherein the land side capacitor pad may be coupled with conductive layers disposed in the coreless substrate. At step 230, a land side capacitor may be coupled with two adjacent land side capacitor pads. At step 240, a solder ball may be formed within each of the openings in the first laminate. At step 250, at least one die may be coupled to the coreless substrate to form a dual sided solder resist coreless package substrate comprising a land side capacitor on a backside side of the coreless package substrate.

The various embodiments of the package structures herein enable the fabrication of low cost, dual sided, coreless substrates comprising dual sided solder resist. Land side capacitors are enabled on the backside of a package structure according to embodiments included herein. LSC on the backside of packages enables ball grid array (BGA) package backside LSC, as well as other types of packages that may utilize LSC incorporation.

In an embodiment, the package substrates of the embodiments herein (such as the package structures depicted in FIG. 1r, for example), may be coupled with various microelectronic devices. The devices may comprise such devices as a microelectronic memory die and a central processing unit (CPU) die in some cases, but may comprise any type of suitable device according to the particular application. In an embodiment, the package substrates/structures herein may comprise a portion of an organic core package, and a coreless, bumpless build up layer (BBUL) package structure, and may comprise PoP packages, through mold vias (TMV), and through silicon vias (TSV).

In an embodiment, the package structures of the embodiments herein may comprise any type of package substrate capable of providing electrical communications between a microelectronic device, such as a die and a next-level component to which the package structures may be coupled (e.g., a circuit board). In another embodiment, the package substrates herein may comprise any suitable type of package structures capable of providing electrical communication between a die and an upper integrated circuit (IC) package coupled with the device layer.

In some embodiments the package substrate/structure may further comprise a plurality of dies, which may be stacked upon one another, depending upon the particular embodiment. In some cases the die(s) may be located/attached/embedded on either the front side, back side or on/in some combination of the front and back sides of a package structure. In an embodiment, the die(s) may be partially or fully embedded in a package structure of the embodiments. The package structure may comprise a multi-chip 3D package or a portion of a system on a chip structure, for example, that may include a central processing unit (CPU) in combination with other devices, in an embodiment.

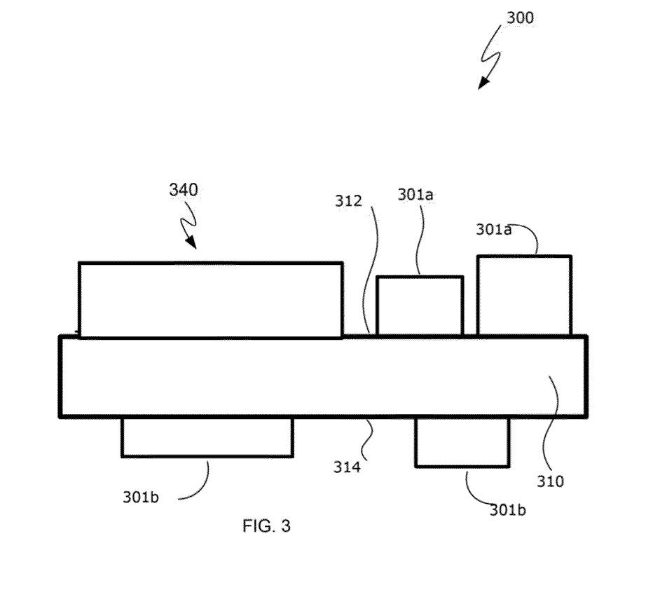

Turning now to FIG. 3, illustrated is an embodiment of a computing system 300. The system 300 includes a number of components disposed on a mainboard 310 or other circuit board. Mainboard 310 includes a first side 312 and an opposing second side 314, and various components may be disposed on either one or both of the first and second sides 312, 314. In the illustrated embodiment, the computing system 300 includes a package structure 340 disposed on the mainboard's first side 312, wherein the package structure 340 may comprise any of the package substrates with molded panel core structure embodiments described herein.

System 300 may comprise any type of computing system, such as, for example, a hand-held or mobile computing device (e.g., a cell phone, a smart phone, a mobile internet device, a music player, a tablet computer, a laptop computer, a nettop computer, etc.). However, the disclosed embodiments are not limited to hand-held and other mobile computing devices and these embodiments may find application in other types of computing systems, such as desk-top computers and servers.

Mainboard 310 may comprise any suitable type of circuit board or other substrate capable of providing electrical communication between one or more of the various components disposed on the board. In one embodiment, for example, the mainboard 310 comprises a printed circuit board (PCB) comprising multiple metal layers separated from one another by a layer of dielectric material and interconnected by electrically conductive vias. Any one or more of the metal layers may be formed in a desired circuit pattern to route—perhaps in conjunction with other metal layers—electrical signals between the components coupled with the board 310. However, it should be understood that the disclosed embodiments are not limited to the above-described PCB and, further, that mainboard 310 may comprise any other suitable substrate.

In addition to the package structure 340, one or more additional components may be disposed on either one or both sides 312, 314 of the mainboard 310. By way of example, as shown in the figures, components 301a may be disposed on the first side 312 of the mainboard 310, and components 301b may be disposed on the mainboard's opposing side 314. Additional components that may be disposed on the mainboard 310 include other IC devices (e.g. processing devices, memory devices, signal processing devices, wireless communication devices, graphics controllers and/or drivers, audio processors and/or controllers, etc.), power delivery components (e.g., a voltage regulator and/or other power management devices, a power supply such as a battery, and/or passive devices such as a capacitor), and one or more user interface devices (e.g., an audio input device, an audio output device, a keypad or other data entry device such as a touch screen display, and/or a graphics display, etc.), as well as any combination of these and/or other devices.

In one embodiment, the computing system 300 includes a radiation shield. In a further embodiment, the computing system 300 includes a cooling solution. In yet another embodiment, the computing system 300 includes an antenna. In yet a further embodiment, the assembly 300 may be disposed within a housing or case. Where the mainboard 4310 is disposed within a housing, some of the components of computer system 300—e.g., a user interface device, such as a display or keypad, and/or a power supply, such as a battery—may be electrically coupled with the mainboard 310 (and/or a component disposed on this board) but may be mechanically coupled with the housing.

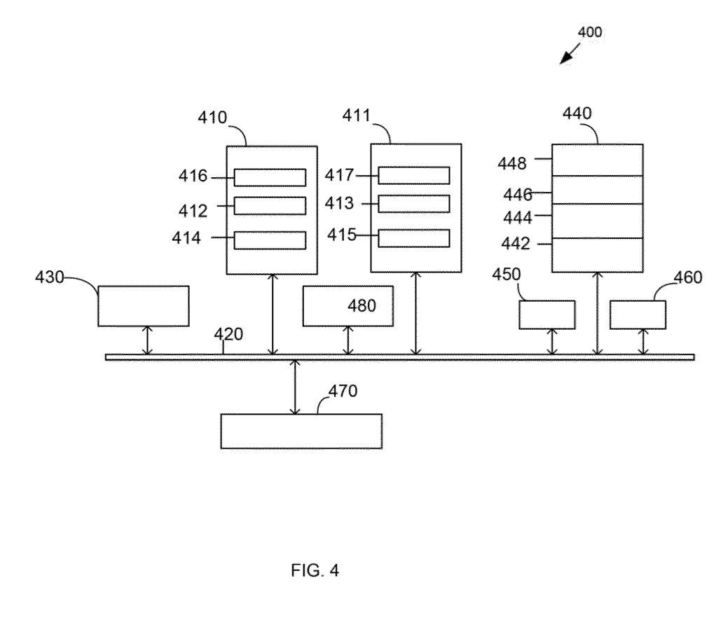

FIG. 4 is a schematic of a computer system 400 according to an embodiment. The computer system 400 (also referred to as the electronic system 400) as depicted can include a package structure/substrate that includes any of the several disclosed embodiments and their equivalents as set forth in this disclosure. The computer system 400 may be a mobile device such as a netbook computer. The computer system 400 may be a mobile device such as a wireless smart phone. The computer system 400 may be a desktop computer. The computer system 400 may be a hand-held reader. The computer system 400 may be integral to an automobile. The computer system 400 may be integral to a television.

In an embodiment, the electronic system 400 is a computer system that includes a system bus 420 to electrically couple the various components of the electronic system 400 The system bus 420 is a single bus or any combination of busses according to various embodiments. The electronic system 400 includes a voltage source 430 that provides power to the integrated circuit 410. In some embodiments, the voltage source 430 supplies current to the integrated circuit 410 through the system bus 420.

The integrated circuit 410 is electrically, communicatively coupled to the system bus 420 and includes any circuit, or combination of circuits according to an embodiment, including the package/device of the various embodiments included herein. In an embodiment, the integrated circuit 410 includes a processor 412 that can include any type of packaging structures according to the embodiments herein. As used herein, the processor 412 may mean any type of circuit such as, but not limited to, a microprocessor, a microcontroller, a graphics processor, a digital signal processor, or another processor. In an embodiment, the processor 412 includes any of the embodiments of the package structures disclosed herein, in an embodiment, SRAM embodiments are found in memory caches of the processor.

Other types of circuits that can be included in the integrated circuit 410 are a custom it or an application-specific integrated circuit (ASIC), such as a communications circuit 414 for use in wireless devices such as cellular telephones, smart phones, pagers, portable computers, two-way radios, and similar electronic systems. In an embodiment, the processor 412 includes on-die memory 416 such as static random-access memory (SRAM). In an embodiment, the processor 412 includes embedded on-die memory 416 such as embedded dynamic random-access memory (eDRAM).

In an embodiment, the integrated circuit 410 is complemented with a subsequent integrated circuit 411. In an embodiment, the dual integrated circuit 411 includes embedded on-die memory 417 such as eDRAM. The dual integrated circuit 411 includes an RFIC dual processor 413 and a dual communications circuit 415 and dual on-die memory 417 such as SRAM. The dual communications circuit 415 may be configured for RF processing.

At least one passive device 480 is coupled to the subsequent integrated circuit 411. In an embodiment, the electronic system 400 also includes an external memory 440 that in turn may include one or more memory elements suitable to the particular application, such as a main memory 442 in the form of RAM, one or more hard drives 444, and/or one or more drives that handle removable media 446, such as diskettes, compact disks (CDs), digital variable disks (DVDs), flash memory drives, and other removable media known in the art. The external memory 440 may also be embedded memory 448. In an embodiment, the electronic system 400 also includes a display device 450, and an audio output 460.

In an embodiment, the electronic system 400 includes an input device such as a controller 470 that may be a keyboard, mouse, touch pad, keypad, trackball game controller, microphone, voice-recognition device, or any other input device that inputs information into the electronic system 400. In an embodiment, an input device 470 includes a camera. In an embodiment, an input device 470 includes a digital sound recorder. In an embodiment, an input device 470 includes a camera and a digital sound recorder.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

What is claimed is:

1. A method of forming a packaging structure comprising:
forming a conductive coating on a first side and on a second side of a core;
forming a conductive plating on the conductive coating disposed on the first and on the second side of the core;
forming build up layers on the conductive plating disposed on the first and second sides of the core to form a dual sided coreless substrate comprising a first panel and a second panel;
de-paneling the first and the second panel of the dual sided coreless substrate from the core;
forming a laminate on a first side and on a second side of the first and second panel to form a first and second coreless substrate;
forming openings in the laminate on the first side and on the second side of the first and second coreless substrate;
forming land side capacitor bumps in the openings disposed on the second side of the first and second coreless substrates;
forming solder balls in the openings disposed on the first side of the first and second coreless substrates; and
attaching a land side capacitor on the land side capacitor bumps.

2. The method of claim 1 further comprising wherein the conductive coating comprises a nickel material, and wherein the conductive plating is plated using an electroless plating process.

3. The method of claim 1 further comprising wherein the build-up layers comprise dielectric layers separated by conductive layers, wherein the conductive layers are formed by at least one of an electrolytic plating and an electroless process.

4. The method of claim 1 further comprising wherein the laminate comprises a solder resist material.

5. The method of claim 1 further comprising herein at least one die is coupled to the package structure.

6. The method of claim 1 further comprising wherein a resist material is formed on the laminate on the build-up layers prior to de-paneling.

7. The method of claim 6 further comprising removing the resist material subsequent to the de-paneling.

8. The method of claim 1 further comprising wherein the conductive coating is removed from the first and second panels after de-paneling.

9. The method of claim 1 further comprising wherein the land side capacitor is attached to two adjacent land side capacitor side pads, wherein the two adjacent land side pads are coupled to the conductive plating.

10. A method of forming a packaging structure comprising:
forming a nickel coating on a first and second side of a prepreg core;
forming a conductive plating on the nickel coating;
forming building up layers on the conductive plating to form a first and second panel disposed on the first and second sides of the prepeg core;
de-paneling the first and second panels from the prepeg core; and
forming a laminate on the first and second sides of the fiat and second panels to form a first and second coreless substrate;
forming at least one conductive bump on a first side of the first and second coreless substrates, and forming a land side capacitor on a second side of the first and second coreless substrates.

11. The method of claim 10 further comprising wherein the laminate comprises a solder resist laminate, and wherein openings are formed in the laminate disposed on the first and second sides of the first and second coreless substrates.

12. The method of claim 11 further comprising forming land side capacitor bumps in the openings of the second sides of the first and second coreless substrates.

13. The method of claim 10 further comprising coupling at least one die to the package structure.

14. The method of claim 12 further comprising wherein the land side capacitor is attached to two adjacent land side capacitor side pads, wherein the two adjacent land side pads are coupled to the conductive plating.

15. The method of claim 10 further comprising wherein the nickel coating further comprises at least one of palladium and gold.

16. The method of claim 10 further comprising herein the prepreg core comprises a copper foil disposed on a dielectric material, wherein the nickel coating is formed on the copper foil.

17. The method of claim 16 further comprising pressing the prepreg core including the nickel coating formed on the copper foil.

18. The method of claim 10 further forming solder pads in the openings of the first sides of the first and second coreless substrates.

19. The method of claim 10 further comprising wherein the conductive plating comprises at least one of a ball grid array pad and a land side capacitor pad.

20. The method of claim 10 further comprising wherein the package structure comprises a portion of a bumpless build up layer package.

21. A package structure comprising:
a first laminate disposed on a first side of a coreless substrate and a second laminate disposed on a second side of the coreless substrate;
at least one solder ball disposed in openings of he first laminate; and
a land side capacitor disposed on the second side of the coreless substrate.

22. The structure of claim 21 further comprising a die coupled to the package structure.

23. The structure of claim 21 further comprising wherein the laminate comprises a solder resist material.

24. The structure of claim 21 further comprising two adjacent interconnect structures disposed on the second side of the coreless substrate, wherein the two adjacent interconnect structures are substantially coplanar and are coupled within the same plane of conductive material disposed within build up layers of the coreless substrate.

25. The structure of claim 24 wherein each of the two adjacent interconnect structures are disposed on adjacent land side capacitor pads.

26. The structure of claim 24 wherein each of the adjacent and side capacitor pads are disposed within openings in the laminate, and are both coupled with a conductive layer disposed within the coreless substrate.

27. The structure of claim 24 wherein the land side capacitor is directly disposed on the two adjacent interconnect structures.

28. The structure of claim 21 wherein the package structure is coupled with a CPU.

29. The structure of claim 21 wherein the package structure comprises a portion of a system on a chip.

30. The package structure of claim 21 further comprising a system comprising:
a bus communicatively coupled to the package structure; and
an eDRAM communicatively coupled to the bus.
